(19) United States
(12) Patent Application Publication
(10) Pub. No.: US 2025/0155827 A1
(43) Pub. Date: May 15, 2025

(54) ACTUATED PHOTOLITHOGRAPHY RETICLE STAGE

(71) Applicant: Massachusetts Institute of Technology, Cambridge, MA (US)

(72) Inventors: Charles Byron Seaberg, Wimberley, TX (US); David L. Trumper, Plaistow, NH (US)

(73) Assignee: Massachusetts Institute of Technology, Cambridge, MA (US)

(21) Appl. No.: 18/941,148

(22) Filed: Nov. 8, 2024

Related U.S. Application Data
(60) Provisional application No. 63/597,411, filed on Nov. 9, 2023.

(51) Int. Cl. G03F 7/00

(52) U.S. Cl. CPC G03F 7/70758; G03F 7/70725

(57) ABSTRACT

A reticle stage for a photolithography scanner having a pneumatic actuation system is disclosed. The pneumatic actuation system may provide a restoring force to a long-stroke stage during scan and turnaround operations. The reticle stage may have or define dual-chamber pneumatic pistons as energy storage devices to create turnaround forces for stage acceleration. As the long-stroke stage is driven by a linear motor a pressure differential is formed between the two pistons providing a net force opposing the direction of the long-stroke stage movement.

### CROSS-REFERENCE TO RELATED APPLICATIONS

The present application claims priority to U.S. Provisional Patent Ser. No. 63/597,411, filed on Nov. 9, 2023, the content of which is hereby incorporated by reference in its entirety.

### STATEMENT REGARDING FEDERALLY SPONSORED RESEARCH OR DEVELOPMENT

Not Applicable.

### FIELD OF TECHNOLOGY

The described technology generally relates to photolithography scanning tools, more particularly to dual-chamber pneumatic devices as energy storage devices to create turnaround forces for long-stroke stage acceleration.

### BACKGROUND

Photolithography is a step in the manufacturing of semiconductor chips. In photolithography, a photosensitive resist covering a silicon wafer is exposed to ultraviolet light in a design pattern which gives the chip its functionality. The pattern is created by modulating an exposure source with a reticle pattern such that the specified pattern of light is focused on the wafer. In modern photolithography scanners, only a slit of light is used to expose the wafer, and the reticle and wafer are moved synchronously relative to the light source using actuators. Actuators must be capable of high forces to accelerate the reticle and wafer quickly, yet also maintain the precision required to adequately align the reticle and wafer during exposure.

Semiconductor photolithography requires the precise actuation of the reticle and wafer stages during the manufacture of integrated circuits. The wafer throughput of a scanning tool is bounded by the velocity and acceleration of the trajectories that the wafer and reticle follow. Maximizing tool throughput (i.e., minimizing manufacture time and maximizing the number of devices made) is an industry concern, given the widespread integration of semiconductors in commercial technologies and the potential of chip shortages. Additionally, reducing overall tool power consumption is important to reduce operating costs and meet sustainability objectives.

### SUMMARY

Aspects of the present disclosure relate to a reticle stage for a photolithography scanner having a pneumatic actuation system for providing a force to a long-stroke stage during scanning and turnaround operations. The reticle stage may have or define dual-chamber pneumatic devices as energy storage devices to create turnaround forces for stage acceleration. As the long-stroke stage is driven, for example by a linear motor, a pressure differential may be formed between the two pneumatic devices providing a restoring force opposite the direction of the long-stroke stage movement.

According to one aspect, a reticle stage system may include a first stage, a linear motor coupled to the first stage and adapted to drive the first stage in a first direction. At least two pneumatic devices may be coupled to opposing sides of the first stage. In response to the driving of the first stage in the first direction, a pressure differential may be formed between the at least two pneumatic devices creating a net force opposing the first direction.

The reticle stage system may further include, alone or in combination, one or more of the following features. The at least two pneumatic devices may comprise at least one piston. At least one sliding seal may be included about the first stage. A gas bearing may be integrated into a sliding seal interface to guide linear motion. The at least two pneumatic devices may be disposed on opposing external sides of the first stage. The at least two pneumatic devices may be disposed on opposing internal sides of the first stage. The at least two pneumatic devices may each comprise at least one piston adjacently disposed on external sides of the first stage. The at least one piston may be disposed in a piston chamber with rigid walls. At least one piston may be disposed in a piston chamber with deformable walls. The deformation of the deformable walls may be passively designed or actively controlled with an actuator. A deformable secondary volume may be disposed inside the piston chamber. The deformation of the secondary volume may be passively designed or may be actively controlled. The at least one piston may be a metal bellows. The at least one piston may be a rolling diaphragm. At least one of the at least two pneumatic devices may be adapted to receive an injected cooling fluid to cool a gas inside at least one of the at least two pneumatic devices. The injected cooling fluid may be a liquid. The at least two pneumatic devices may comprise end walls that can be positionally changed to accommodate different scan lengths. First and second actuators may be respectively coupled to the end walls of the at least two pneumatic devices. The first and second actuators may be ball screws. A pressure of the at least two pneumatic devices may be actively controlled by adding and removing fluid to a piston chamber.

According to another aspect, a system may include a long-stroke stage, and a linear motor coupled to the long-stroke stage. The linear motor may be adapted to drive the long-stroke stage in a first direction. At least two pistons may be coupled to opposing sides of the long-stroke stage. In response to the driving of the long-stroke stage in the first direction, a pressure differential may be formed between the at least two pistons creating a net force opposing the first direction.

The system may further include, alone or in combination, one or more of the following features. The at least two pistons may be disposed on opposing external sides of the long-stroke stage. At least one of the at least two pistons may be actively controlled by adding and removing fluid to a piston chamber.

According to another aspect, a system may include a wafer stage configured to support a wafer during a photolithography operation, and a reticle actuation system configured to support a reticle. The reticle actuation system may include a first stage, and a linear motor coupled to the first stage. The linear motor may be adapted to drive the first stage in a first direction. At least two pneumatic devices may be coupled to opposing sides of the first stage. In response to the driving of the first stage in the first direction, a pressure differential may be formed between the at least two pneumatic devices creating a net force opposing the first direction. An optical system may include an illumination source and at least one optical element configured to optically couple a signal from the illumination source to the reticle actuation system and the wafer stage during the photolithography operation.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, aspects of the present disclosure are illustrated by way of example and not limitation in the figures, in which.

FIG. 1 is a block diagram of a photolithography scanner system, according to one aspect of the disclosure.

FIG. 2A is a top-view of a reticle stage system with a dual-chamber pneumatic device external to a long-stroke stage, according to one aspect of the disclosure.

FIG. 2B is a top-down view of the reticle stage system of FIG. 2A during long-stroke actuation, according to one aspect of the disclosure.

FIG. 3 is a top-down view of a reticle stage system with a dual-chamber pneumatic device internal to the long-stroke stage, according to one aspect of the disclosure.

FIG. 4 is a top-down view of a reticle stage system having a variable pressure pneumatic device, according to one aspect of the disclosure.

FIG. 5 is a top-down view of an alternative reticle stage system having a variable pressure pneumatic device, according to one aspect of the disclosure.

FIG. 6 is a diagram of an example of a computing device, according to one or more aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

Modern photolithography scanners move a reticle along a scan axis at a constant velocity during exposure. The reticle moves back and forth repeatedly with this constant velocity, and during each scan, the pattern on the reticle may be transferred to the wafer in alternating directions.

Between scan exposures a turnaround operation is executed in which a large force is applied to the reticle stage with actuators. During turnaround, the wafer may be simultaneously repositioned to place a new field in the pathway for exposure. Minimization of reticle turnaround time may be desirable to increase machine throughput (e.g., wafers per hour). In order to improve turnaround operations, pneumatic springs or devices may be utilized to create turnaround forces for stage acceleration and reduce power consumption in a lithography system.

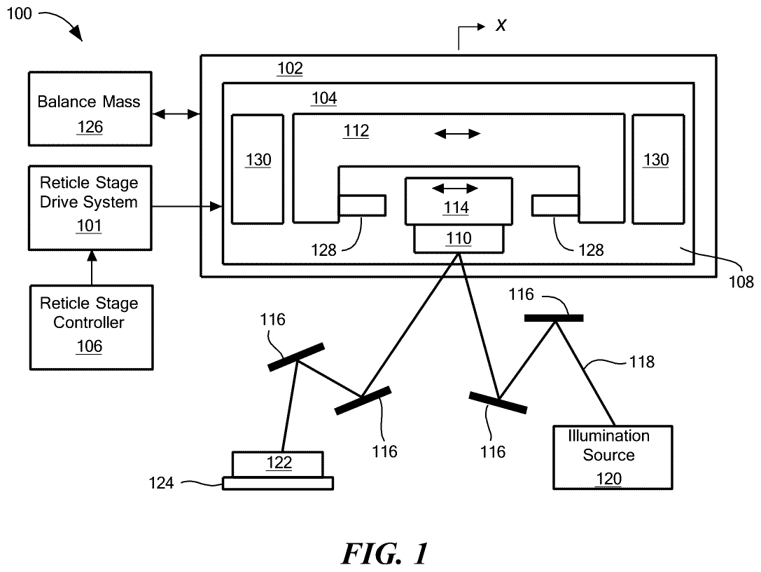

Referring now to FIG. 1, a photolithography system 100 may include a reticle actuation system 102 that may include a reticle stage drive system 101 coupled to a reticle stage 104. According to one aspect, the reticle stage drive system 101 may include a linear motor and may be used to magnetically levitate and move the reticle stage 104. Thus, the reticle actuation system 102 may operate such that in response to signals from a reticle stage controller 106, the reticle stage 104 may move during scan and turnaround operations.

Reticle stage 104 may be disposed in an enclosure 108. It should be noted that enclosure 108 may be coupled to a vacuum system (not explicitly shown in FIG. 1) capable of evacuating fluid (e.g., air) from enclosure 108. Thus, enclosure 108 may correspond to a vacuum chamber. It should also be appreciated that the reticle stage 104 may move within a vacuum environment. Furthermore, in the case where the photolithography system 100 is a next-generation photolithography system (e.g., an extreme ultraviolet (EUV) system) then the reticle stage 104 may move in an ultra-clean high-vacuum environment, as would be readily understood by one skilled in the art.

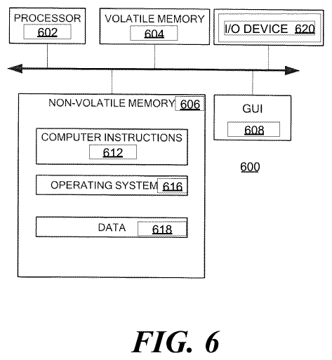

Reticle stage controller 106 may issue control signals or commands to control movement of the reticle stage 104. The reticle stage controller 106 may include, for example, control circuitry and software which provides signals to initiate movement (e.g., position reference signals profiles) of reticle stage 104 between one or more positions. The reticle stage controller may be, or may include, a computing device such as the computing device 600 described in connection with FIG. 6. The reticle stage controller 106 may also be capable of performing real-time control for motion and magnetic suspensions of the reticle stage 104. That is, the reticle stage controller 106 may include an active control capability, which may read sensor signals and send controlling commands to drive the actuators and drive motors for the reticle stage 104, as described herein.

The reticle stage 104 may include a long-stroke stage 112 and short-stroke stage 114, to which a reticle 110 is clamped. The long-stroke stage 112 may have a larger travel and follow the reticle trajectory within several micrometers. The short-stroke stage 114 may be restricted to remain within about +0.5 millimeters (mm) of the long-stroke stage 112 but is intended to follow the reticle trajectory with sub-nanometer error. According to one aspect, to achieve the required accuracy and precision, the short-stroke stage 114 may be magnetically levitated and controlled in six degrees-of-freedom (DOF) using short-stroke actuators 128 mounted to the long-stroke stage 112 with corresponding components on the short-stroke stage 114.

The reticle stage drive system 101 of the reticle actuation system 102 may be capable of moving the reticle 110 during scan and turnaround operations. During turnaround, a linear motor mounted to the long-stroke stage 112 may be used to provide force in the scan direction to move the reticle stage 104 by way of the long-stroke stage.

According to one aspect, the reticle actuation system 102 may include one or more pneumatic devices 130, described in greater detail below, including one or more pneumatic cylinders as energy storage devices to create turnaround forces for reticle stage 104 acceleration. As used herein, “pneumatic device” may refer to a fluid-filled mechanical apparatus capable of energy conversion between mechanical and pneumatic domains. In other words, mechanical work done on the actuator may yield an increase in the internal energy of the enclosed working gas. Similarly, mechanical work done by the actuator may result in a decrease in internal energy of the enclosed working gas. One example of such a device may include one or more pneumatic cylinders having, for example, a piston and a piston chamber. The one or more pneumatic devices may be disposed on opposing sides of the long-stroke stage 112, and each may include an equal bias pressure such that the long-stroke stage 112 is under zero net force when at a center position of the reticle stage system 102.

In operation, the reticle 110 may be disposed in a vacuum chamber which contains optical elements 116 which may reflect or otherwise direct a signal 118 (e.g., a light or laser signal) from an illumination source 120 toward a substrate, such as a wafer 122. The wafer 122 may be disposed on a moveable wafer stage 124. During a scan operation, the illumination source 120 may transmit the signal 118 through the optical elements 116, through the reticle 110 so as to produce a desired pattern on the wafer 122. It should be appreciated that not all of the elements in the photolithography system 100 are shown in FIG. 1. For simplicity and to promote clarity in FIG. 1, some conventional components necessary to use and direct light to transfer a desired geometric pattern from the reticle to a substrate have not been shown in FIG. 1, however such elements and their functionality would be well-understood by a person skilled in the art. While the optical paths drawn in FIG. 1 are reflective, optical elements may also be transmissive like those commonly used in DUV tools.

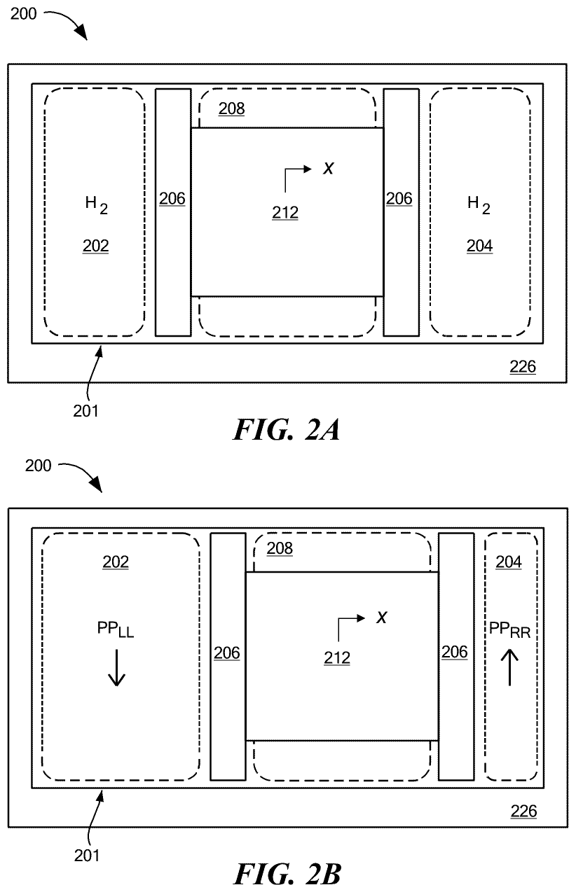

The reticle stage 104 may be coupled to a balance mass 126 to avoid transmission of reaction forces into the frame of the photolithography system 100 when the reticle stage 104 is accelerating. These reaction forces include both the forces from pneumatic devices 130 and the long-stroke linear motor in the reticle stage drive system 101. While the balance mass 126 is shown in FIG. 1 apart from the reticle stage, one skilled in the art will recognize that such a depiction is conceptual and, as detailed below, the balance mass 126 may be integrated with the reticle stage 104 such that the pneumatic devices 130 are disposed between and act on the balance mass 126 and the long-stroke stage 112, particularly as shown connection with FIGS. 2-5.

While the photolithography system 100 and its exemplary optics depicted in FIG. 1 may be configured for extreme ultraviolet lithography (EUV), one skilled in the art will recognize that the concepts, systems, and methods described herein may also be implemented in a deep ultraviolet (DUV) tool without deviating from the scope of the present disclosure. Further, while a vacuum enclosure 108 is depicted as a component of the EUV system of FIG. 1, in a DUV tool, a vacuum like enclosure 108 may not be needed.

Referring now to FIGS. 2A-2B, a reticle stage system 200 may include a double-sided pneumatic device 201. The pneumatic device 201 may include or be formed by one or more rigid and sealed piston chambers that may include substantially insulated cylinder walls to reduce heat losses. According to one aspect, the pneumatic device 201 may include a first piston chamber 202 and a second piston chamber 204 disposed on opposing sides of a long-stroke stage 212. As described herein, the piston chambers 202, 204 may also be fluid-tight having no leakage through frictionless seals. A balance mass 226 may be disposed about the perimeter of the pneumatic device 201 and long-stroke stage 212. Pistons 206 may be disposed on opposing sides of the long-stroke stage 212, between the long-stroke stage 212 and the respective piston chambers 202, 204. The pistons 206 may act as sliding seals in conjunction with the piston chambers 202, 204 to form pneumatic cylinders. According to one aspect, a bearing may be integrated into the interface between the pistons 206 and piston chambers 202,204 which may be used to guide linear motion of the pistons 206 along the scan axis. The piston chambers 202, 204 may be filled with a pressurized fluid or gas, such as hydrogen gas. The pistons 206 may separate the pressurized gas from the long-stroke stage 212 to form a vacuum 208. The pressurized gas in the piston chambers 202, 204, according to one aspect, may act on the crowns of the pistons 206 and on the long-stroke stage 212 to provide acceleration forces, as described below.

According to one aspect, to decrease power consumption of a photolithography system, like the photolithography system 100 of FIG. 1, reactive energy storage may be used advantageously during scan turnaround operations. For example, at the end of travel of the long-stroke stage 212, the kinetic energy of the stage may be converted to the internal energy of a working gas that may, in return, flow back into kinetic energy of the long-stroke stage 212.

According to one aspect, the use of the reactive energy storage in the piston chambers 202, 204 may reduce the required coil cooling in a long-stroke linear motor due to reduced ohmic losses in the motor coils. In addition, the reduction of required long-stroke motor mechanical power during turnaround operations may reduce requirements for the motor's power amplifier. Further, such reactive storage from the piston chambers 202, 204, may allow significant reduction in the total power consumption of the motion axes of the photolithography system.

According to one aspect, the pneumatic device 201 may include equal bias pressure filling each of the first piston chamber 202 and the second piston chamber 204. This may ensure that there is zero net force acting on the long-stroke stage 212 when it is at the center position. During a scan operation, a linear motor may actuate the long-stroke stage 212 driving the long-stroke stage 212 in a scan direction, denoted ‘x’. As the long-stroke stage 212 travels during a scan operation, as shown in FIG. 2B as moving from left to right, a pressure imbalance may occur. As the long-stroke stage 212 moves to the right, the first piston chamber 202 may increase in volume (a decrease in pressure P_{LL}) while the second piston chamber 204 reduces in volume (an increase in pressure P_{RR}). The resulting pressure imbalance may impart a reactive net force on the long-stroke stage 212 back to the left. According to one aspect, once the linear motor begins the movement of the long-stroke stage 212 in the scan direction, the reactive forces in the first and second piston chambers 202, 204 may operate to decrease the required work from the linear motor to maintain an oscillatory trajectory.

In one aspect, a pressure integrated over the piston crown area A may create a force acting as a positive nonlinear spring, thereby providing a restoring force from the compressed gas in the second piston chamber 204 towards the center position. This may be described as:

$${m}_{L S} {\ddot{x}}_{s c a n} = - ( {P}_{R} - {P}_{L )} A \qquad ( 1 )$$

in which m_{LS} is the mass of the long-stroke stage 212, \ddot{x}_{scan} is the acceleration of the long-stroke stage 212 in the scan axis, A is the projected area of the piston crown which the pressure acts on, and P_{R} and P_{L} is the gas pressure in the right and left chambers 202, 204, respectively.

As a net force from the compressed gas in the piston chambers 202, 204 may exist during scan operations as well as turnaround operations, the long-stroke linear motor may be used to provide a force sufficient to cancel the pneumatic force during a scan operation in order to maintain a constant velocity trajectory. According to one aspect, the force contribution from the compressed second piston 204 during a scan operation may be mapped via an algorithm such as iterative learning control and may be accurately cancelled out during subsequent scans.

According to one aspect, the optics and reticle in an EUV lithography tool may be disposed to function in a vacuum 208. Accordingly, the separation of compressed gas in the piston chambers 202, 204 from the vacuum area 208 may be an important part of integration. According to one aspect, a differentially pumped air bearing may be used as a sliding seal to guide linear motion and separate the compressed gas in piston chambers 202, 204 from vacuum 208.

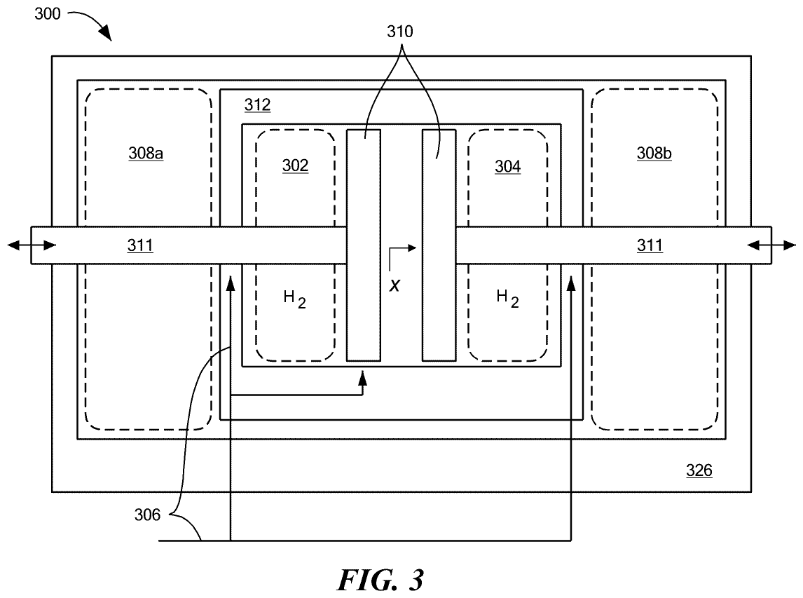

FIG. 3 is a top-down view of a reticle stage system 300 including an alternative pneumatic device 301 disposed internal to a long-stroke stage 312. According to one aspect, and as a person of ordinary skill in the art will recognize, the reticle stage system 300 shown in FIG. 3 may also be a side-view. A balance mass 326 may be disposed about the perimeter of the long-stroke stage 312, however the balance mass 326 may extend beyond, for example, the width of the long-stroke stage 312 to accommodate one or more vacuum chambers 308a, 308b disposed between the balance mass 326 and opposing sides of the long-stroke stage 312. A first piston chamber 302 and second piston chamber 304 may be disposed within the long-stroke stage 312. Each of the first and second piston chambers 302, 304 may include an end wall 310. In operation, the gas in piston chambers 302, 304 may act similarly to previously described configurations in that as the long-stroke stage 312 is moved, one piston chamber pressure may increase, while the other decreases. The pressure differential may create a net force counter to the direction of the moving long-stroke stage 312.

According to one aspect, the scan length of the reticle stage system 300 may be changed by moving the end walls 310 of the first and second piston chambers 302, 304, thusly increasing or decreasing the volume of the chambers. According to one aspect, the end walls 310 may be coupled to the balance mass 326 by a linear actuator 311, such as a ball screw or the like. Actuation of the linear actuator 311 in one of two directions may drive the end walls 310 in adjustment with a desired scan length.

According to one aspect, and similarly to bearings described herein, the reticle stage system 300 may include differentially pumped air bearings 306 to create a sliding seal isolating the first and second piston chambers 302, 304 from the vacuum chambers 308a, 308b, respectively.

The reticle stage systems shown in FIGS. 2A-B and FIG. 3 may rely on a linear motor coupled to the long-stroke stage for moving the stage in the scan direction. According to one aspect, one linear motor geometry which may better accommodate a cylindrical piston is a tubular motor geometry.

According to one or more aspects of the present disclosure, the pressure inside the pneumatic devices may be actively controlled. The active control of chamber pressure may be accomplished via the addition or removal of fluid into the piston chamber, or the actuation of piston chamber walls the change the effective volume of the piston chamber. Accordingly, direct flow of pressurized gas in and out of the piston chamber may be achieved through the use of one or more control valves used to add to or remove gas from a piston chamber. While the introduction of active control may add complexity to the pneumatic device, doing so may allow the system to achieve a force from the implemented pistons that more closely resembles the ideal turnaround acceleration and further reduce the work required from the long-stroke actuator to maintain an oscillatory trajectory.

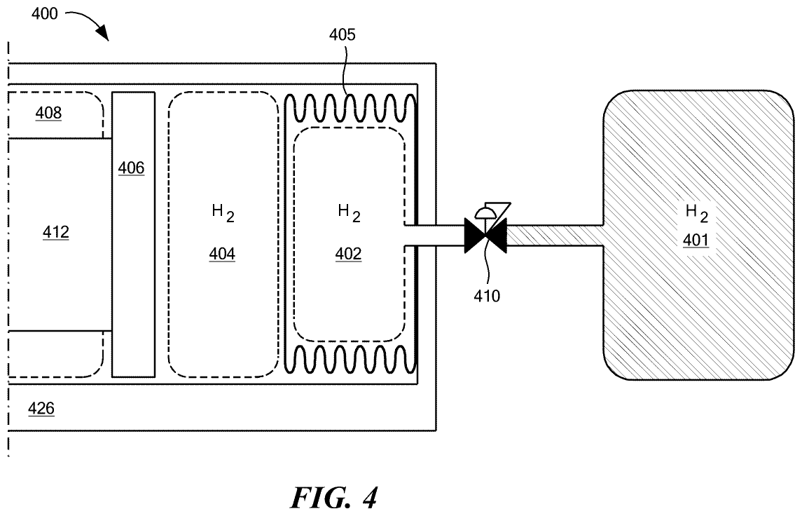

According to one aspect, in contrast to implementing pneumatic devices with rigid walls like a standard pneumatic cylinder, a pneumatic device may utilize one or more compliant mechanisms placed inside or integrated into the walls of the pneumatic chamber that change shape throughout a reticle trajectory in order to change the effective volume of the pneumatic chamber. By changing the effective volume of the pneumatic chamber, the gas pressure which acts on the piston may be varied. Furthermore, the deformation of compliant members may either be actively controlled via actuators (pneumatic, hydraulic, electromagnetic, piezoelectric, etc.) or passively coupled to the trajectory (via pressure, temperature, stage position, etc.). FIG. 4 is a partial top-down view of a reticle stage system 400 featuring variable pressure regulation, according to aspects of the present disclosure. While the partial view of FIG. 4 depicts only one side of the reticle stage system 400, the opposing side of the system may be substantially similar, as would be understood by a person of ordinary skill in the art.

In one aspect, one or more reservoirs 401 of a pressurized fluid, such as hydrogen gas, may be in fluid communication, through a pressure regulator 410, with a sealed volume, such as a first piston chamber 402. According to one aspect, the first piston chamber 402 may be disposed in or part of a compliant mechanism, such as a metal bellows 405. The metal bellows 405 may be contained within a piston chamber 404. The piston chamber 404 may be separated and isolated from a long-stroke stage 412 by a sealed piston 406, maintaining a vacuum chamber 408 about the long-stroke stage 412. According to one aspect, the first piston chamber 402 may be pressurized by the hydrogen gas supplied by the reservoir 401. The pressure of first piston chamber 402 and geometry of the metal bellows 405 may be actively controlled and/or passively designed to deform throughout the trajectory. Since the metal bellows 405 is disposed inside the piston chamber 404, an increase in the bellows volume may compress gas molecules in the piston chamber 404 outside of the metal bellows 405, resulting in an increase in pressure in the piston chamber 404. Similarly, a decrease in the bellows volume may result in a decrease in the pressure in piston chamber 404. In such a manner, the pressure force applied to the long-stroke stage 412 may be indirectly varied via passive or active deformation of metal bellows 405.

According to one aspect, at least one of the reservoirs may include a cooling fluid, such as hydrogen in a liquid or supercritical phase, in order to quickly add gas (and thus pressure) to the chamber. Injection of liquid hydrogen may provide higher volumetric density fluid injections and reduce the time required to add gas to the first piston chamber 402. Once the fluid is inside the first piston chamber 402, it may expand and undergo a gas phase transition.

According to one aspect, it may be advantageous to add and remove gas from the first piston chamber 402 in order to decrease the gas temperature in the piston. If an external supply of compressed gas is being added, the gas in the first piston chamber 402 may not need to reach the same compression ratio. Furthermore, if a liquid form of the gas were added to the first piston chamber 402, the latent heat of vaporization may result in additional cooling of the gas in the piston. Decreased gas temperature may reduce thermal losses and ease the mechanical design of piston chamber 402 and sliding seals.

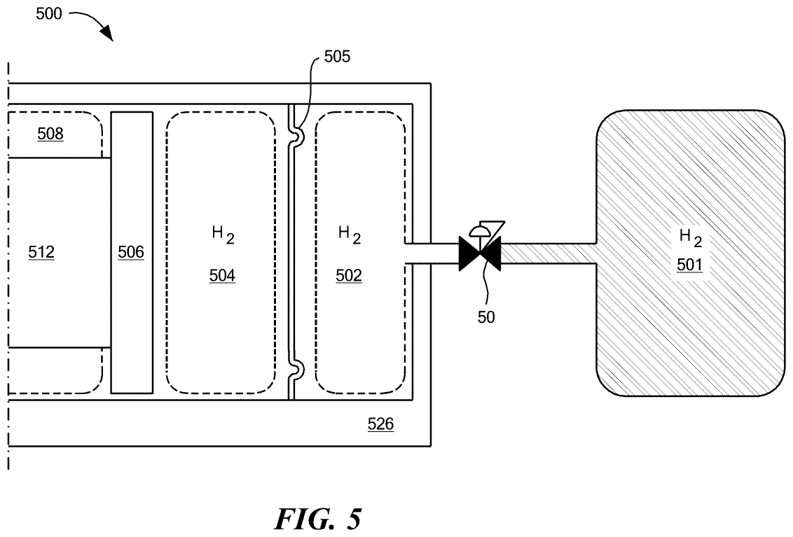

FIG. 5 is a partial top-down view of a reticle stage system 500, featuring alternative variable pressure regulation, according to aspects of the disclosure. While the partial view of FIG. 5 depicts one side of the reticle stage system 500, the opposing side of the system may be substantially similar, as would be understood by a person of ordinary skill in the art.

The reticle stage system 500 may differ from the system 400 shown in FIG. 4, by replacing the metal bellows 405 with another compliant mechanism, such as a rolling diaphragm bellows 505. A reservoir 501 of a pressurized fluid, such as hydrogen gas, may be in fluid communication, through a pressure regulator 510, with a first piston chamber 502. According to one aspect, the first piston chamber 502 may be disposed adjacent to the rolling diaphragm bellows 505. The rolling diaphragm bellows 505 may be adjacent to, and act upon, a second piston chamber 504. The second piston chamber 504 may be separated and isolated from a long-stroke stage 512 by a sealed piston 506, maintaining a vacuum chamber 508 about the long-stroke stage 512. According to one aspect, the first piston chamber 502 may be pressurized by the hydrogen gas supplied by the reservoir 501. Once the first piston chamber 502 pressure reaches a maximum, the pressure of the rolling diaphragm bellows 505 may deform to keep the pressure at the maximum for the duration of a turnaround operation. Accordingly, a reactive force may be applied to the long-stroke stage 512 in response to the stage's movement to the right, for example.

While aspects of the disclosure provide for a pressure-controlled metal bellows, such as metal bellows 405 (FIG. 4) or a rolling diaphragm, such as rolling diaphragm 505 (FIG. 5) built into an end wall, one skilled in the art will recognize that other volumetric devices may be integrated to control the pressure. For example, one or more of a piezo stack actuator, a ball screw with a plunger, a mechanical spring, or the like may be integrated to control the pressure in the pneumatic devices.

Referring to FIG. 6, in some embodiments, a computing device 600, such as a controller, driver, or the like, may include processor 602, volatile memory 604 (e.g., RAM), non-volatile memory 606 (e.g., a hard disk drive, a solid-state drive such as a flash drive, a hybrid magnetic and solid-state drive, etc.), graphical user interface (GUI) 608 (e.g., a touchscreen, a display, and so forth) and input/output (I/O) device 620 (e.g., a mouse, a keyboard, etc.). Non-volatile memory 606 stores computer instructions 612, an operating system 916 and data 618 such that, for example, the computer instructions 612 are executed by the processor 602 out of volatile memory 604. Program code may be applied to data entered using an input device of GUI 608 or received from I/O device 620.

Based on the teachings, one skilled in the art should appreciate that the scope of the present disclosure is intended to cover any aspect of the present disclosure, whether implemented independently of or combined with any other aspect of the present disclosure. For example, an apparatus may be implemented or a method may be practiced using any number of the aspects set forth. In addition, the scope of the present disclosure is intended to cover such an apparatus or method practiced using other structure, functionality, or structure and functionality in addition to, or other than the various aspects of the present disclosure set forth. It should be understood that any aspect of the present disclosure may be embodied by one or more elements of a claim.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

As used herein, the term “determining” encompasses a wide variety of actions. For example, “determining” may include calculating, computing, processing, deriving, investigating, looking up (e.g., looking up in a table, a database or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

The various illustrative logical blocks, modules and circuits described in connection with the present disclosure may be implemented or performed with a processor specially configured to perform the functions discussed in the present disclosure. The processor may be a neural network processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. Alternatively, the processing system may comprise one or more neuromorphic processors for implementing the neuron models and models of neural systems described herein. The processor may be a microprocessor, controller, microcontroller, or state machine specially configured as described herein. A processor may also be implemented as a combination of computing devices, e.g., a combination of a DSP and a microprocessor, a plurality of microprocessors, one or more microprocessors in conjunction with a DSP core, or such other special configuration, as described herein.

The steps of a method or algorithm described in connection with the present disclosure may be embodied directly in hardware, in a software module executed by a processor, or in a combination of the two. A software module may reside in storage or machine readable medium, including random access memory (RAM), read only memory (ROM), flash memory, erasable programmable read-only memory (EPROM), electrically erasable programmable read-only memory (EEPROM), registers, a hard disk, a removable disk, a CD-ROM or other optical disk storage, magnetic disk storage or other magnetic storage devices, or any other medium that can be used to carry or store desired program code in the form of instructions or data structures and that can be accessed by a computing system. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and processing, including the execution of software stored on the machine-readable media. Software shall be construed to mean instructions, data, or any combination thereof, whether referred to as software, firmware, middleware, microcode, hardware description language, or otherwise.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or specialized register files. Although the various components discussed may be described as having a specific location, such as a local component, they may also be configured in various ways, such as certain components being configured as part of a distributed computing system.

The machine-readable media may comprise a number of software modules. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a special purpose register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any storage medium that facilitates transfer of a computer program from one place to another.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means, such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A reticle stage system comprising:
a first stage;
a linear motor coupled to the first stage and adapted to drive the first stage in a first direction;
at least two pneumatic devices coupled to opposing sides of the first stage;
wherein in response to the driving of the first stage in the first direction, a pressure differential is formed between the at least two pneumatic device creating a net force opposing the first direction.

2. The reticle stage system of claim 1 wherein the at least two pneumatic devices each comprise at least one piston.

3. The reticle stage system of claim 1 further comprising at least one sliding seal about the first stage.

4. The reticle stage system of claim 3 wherein a gas bearing is integrated into a sliding seal interface to guide linear motion.

5. The reticle stage system of claim 1 wherein the at least two pneumatic devices are disposed on opposing external sides of the first stage.

6. The reticle stage system of claim 1 wherein the at least two pneumatic devices are disposed on opposing internal sides of the first stage.

7. The reticle stage system of claim 1 wherein the at least two pneumatic devices each comprise at least one piston adjacently disposed on external sides of the first stage.

8. The reticle stage system of claim 7 wherein at least one piston is disposed in a piston chamber with rigid walls.

9. The reticle stage system of claim 7 wherein at least one piston is disposed in a piston chamber with deformable walls.

10. The reticle stage system of claim 9 wherein, a deformation of the deformable walls may be passively designed or actively controlled with an actuator.

11. The reticle stage system of claim 9, further comprising a deformable secondary volume disposed inside the piston chamber.

12. The reticle stage system of claim 11 wherein deformation of the secondary volume may be passively designed.

13. The reticle stage system of claim 11 wherein deformation of the secondary volume may be actively controlled.

14. The reticle stage system of claim 7 wherein the at least one piston includes a metal bellows.

15. The reticle stage system of claim 7 wherein the at least one piston includes a rolling diaphragm.

16. The reticle stage system of claim 1 wherein at least one of the at least two pneumatic devices is adapted to receive an injected cooling fluid to cool a gas inside at least one of the at least two pneumatic devices.

17. The reticle stage system of claim 16 wherein the injected cooling fluid is a liquid.

18. The reticle stage system of claim 17 wherein the at least two pneumatic devices comprise end walls that can be positionally changed to accommodate different scan lengths.

19. The reticle stage system of claim 18 further comprising first and second actuators respectively coupled to the end walls of the at least two pneumatic devices.

20. The reticle stage system of claim 19 wherein the first and second actuators are ball screws.

21. The reticle stage system of claim 1 wherein a pressure of the at least two pneumatic devices is actively controlled by adding and removing fluid to a piston chamber.

22. A system comprising:
a long-stroke stage;
a linear motor coupled to the long-stroke stage and adapted to drive the long-stroke stage in a first direction; and
at least two pistons coupled to opposing sides of the long-stroke stage;
wherein in response to the driving of the long-stroke stage in the first direction, a pressure differential is formed between the at least two pistons creating a net force opposing the first direction.

23. The system of claim 22 wherein the at least two pistons are disposed on opposing external sides of the long-stroke stage.

24. The system of claim 22 wherein a pressure of at least one of the at least two pistons is actively controlled by adding and removing fluid to a piston chamber.

25. A system comprising:
a wafer stage configured to support a wafer during a photolithography operation;
a reticle actuation system configured to support a reticle, the reticle actuation system including:
a first stage;
a linear motor coupled to the first stage and adapted to drive the first stage in a first direction; and
at least two pneumatic devices coupled to opposing sides of the first stage;
wherein in response to the driving of the first stage in the first direction, a pressure differential is formed between the at least two pneumatic devices creating a net force opposing the first direction; and
an optical system including an illumination source and at least one optical element configured to optically couple a signal from the illumination source to the reticle actuation system and the wafer stage during the photolithography operation.
